(19) United States
(12) Patent Application Publication
(10) Pub. No.: US 2012/0098144 A1
(43) Pub. Date: Apr. 26, 2012

(54) VERTICAL ELECTRODE STRUCTURE USING TRENCH AND METHOD FOR FABRICATING THE VERTICAL ELECTRODE STRUCTURE

(75) Inventors: Gyu-Tae KIM, Gwangmyeong-si (KR); So-Jeong PARK, Seoul (KR); Dae-Young JEON, Seoul (KR); Yun-Jeong KIM, Seoul (KR)

(73) Assignee: KOREA UNIVERSITY RESEARCH AND BUSINESS FOUNDATION, Seoul (KR)

(21) Appl. No.: 13/280,824

(22) Filed: Oct. 25, 2011

(30) Foreign Application Priority Data
Oct. 25, 2010 (KR) 10-2010-0104029

(51) Int. Cl. H01L 23/48; H01L 21/768

(52) U.S. Cl. 257/774; 438/675; 257/E21.586; 257/E23.011

(57) ABSTRACT

Provided is a vertical electrode structure using a trench and a method of manufacturing the vertical electrode structure. The method of forming a vertical electrode structure using a trench includes steps of: forming the trench on a predetermined region of a semiconductor substrate; and forming electrode layers in predetermined regions of inner and outer portions of the trench. In this manner, the electrode deposition in the vertical direction is established by using the trench, so that it is possible to form a deposited electrode having a size of several hundred nm or less by a short processing time and a low processing cost.

### BACKGROUND OF THE INVENTION

1. Field of the Invention

The present invention relates to a semiconductor device structure and, more particularly, to an electrode structure in a semiconductor device.

2. Description of the Related Art

In an article disclosed in Biosensors and Bioelectronics in 2009, it is known that, if the electrode spacing is decreased and the number of electrodes is increased, reaction sensitivity is increased. A capacitance of an element is defined by C=εA/d. As the number of electrodes is increased, the total area A of electrode is increased. As the electrode spacing is decreased, the total capacitance is increased.

In terms of resistance, as the cross section of the channel through which a current can be flowed is increased and the length of the channel is decreased, the value of resistance is decreased. The amount of the measured current may be increased.

In the conventional technology, in order to obtain this effect, an interdigitated electrode structure may be used. FIG. 1 is a view illustrating an example of the interdigitated electrode.

In order to form the interdigitated electrode structure, a photolithography process is needed. The photolithography is a lithography method of selectively irradiating UV light on a photosensitive material which reacts with UV light and using the occurring denaturalization. Since the photolithography process takes a vary short time and can be used for a large-area process, the photolithography process is widely used in a typical semiconductor process.

However, since the resolution of the photolithography depends on the wavelength of UV light, there is a problem in that, although a structure having a size of several micrometers (um) can be manufactured, it is difficult to manufacture a structure having a size of several hundreds of nanometers (nm) or less.

In order to avoid the problem, electron beam lithography process using a short wavelength electron beam may be used. However, since a long processing time is taken and the process cost is high, the electron beam lithography process is not suitable for a large-area process.

### SUMMARY OF THE INVENTION

The present invention is to provide a method of depositing electrodes having a size of several hundreds of nanometers or less and forming the electrodes with a short processing time and a low processing cost.

According to an aspect of the present invention, there is provided a method of forming a vertical electrode structure using a trench, including steps of: forming the trench on a predetermined region of a semiconductor substrate; and forming electrode layers in predetermined regions of inner and outer portions of the trench. In this manner, the electrode deposition in the vertical direction is established by using the trench, so that it is possible to form a deposited electrode having a size of several hundred nm or less by a short processing time and a low processing cost.

The electrode layer may be formed by using a deposition process. In this case, a thickness of each of the deposited electrodes is adjusted by controlling an electrode deposition time, so that it is possible to easily adjust an electrode spacing.

The deposition process may be performed in the state where the substrate is tilted in a predetermined direction. In the case where the substrate is tilted in a trench sidewall direction, the adjustment of the electrode spacing can be more easily performed. In the case where the substrate is tilted in the direction parallel to the trench sidewall direction, although a highly flexible metal is deposited, it is possible to prevent undesired short-circuit between the electrodes.

The electrode layer may be formed as a plurality of electrode layers which are separated from each other by insulating layers. In this case, the vertical electrode structure can be implemented in more various forms.

In addition, the method of forming a vertical electrode structure using a trench may further include steps of: coating a predetermined liquid material on the substrate and curing the liquid material; and detaching the cured material, to which the electrode layer is transferred from the substrate, from the substrate. In this case, the material may be polydimethylsiloxane (PDMS). According to this configuration, it is possible to easily form the vertical electrode structure on the flexible substrate such as PDMS.

In addition, according to another aspect of the present invention, there is provided a vertical electrode structure manufactured by using the aforementioned method.

According to the present invention, it is possible to deposit electrodes having a size of several hundreds of nanometers or less with a short processing time and a low processing cost.

### BRIEF DESCRIPTION OF THE DRAWINGS

FIG. 1 is a view illustrating an example of an interdigitated electrode.

FIG. 2 is a schematic flowchart illustrating a vertical electrode structure forming method using a trench according to an embodiment of the present invention.

FIG. 3 is a view illustrating an example of a trench structure.

FIG. 4 is a flowchart illustrating a process of forming a vertical electrode structure using a trench having a plurality of electrode layers.

FIG. 5 is a flowchart illustrating a process of performing electrode extension by using a left-right slope.

FIG. 6 is a flowchart illustrating a process of performing electrode extension by using an up-down slope.

FIG. 7 is a flowchart illustrating a process of transferring an electrode pattern to a flexible substrate.

FIG. 8 is a flowchart illustrating a process of forming an electrode using an interdigitated electrode pattern.

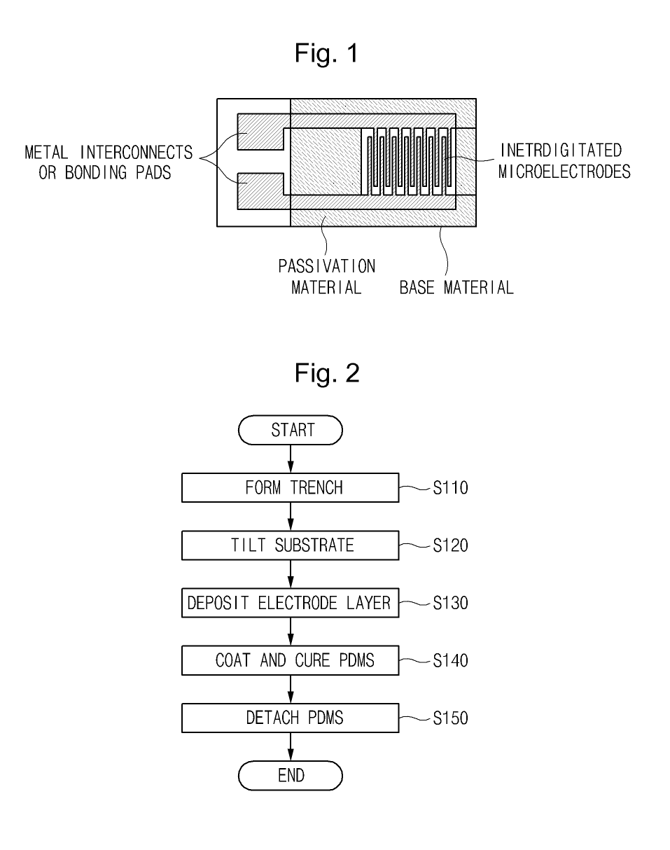

### DESCRIPTION OF THE PREFERRED EMBODIMENTS

Hereinafter, preferred embodiments of the present invention will be described with reference to the attached drawings.

FIG. 2 is a schematic flowchart illustrating a vertical electrode structure forming method using a trench according to an embodiment of the present invention.

In FIG. 2, first, the trench is formed in a pre-defined region of a semiconductor substrate (S110). Herein, the predetermined region denotes a region on the semiconductor substrate, which is defined in advance by a semiconductor designer or the like in order to form the trench.

As described in the Background Art, the problems occur because the electrodes are arrayed parallel to the direction of the substrate. If the electrodes are designed to be arrayed perpendicular to the direction of the substrate, it is possible to avoid difficulty in the process.

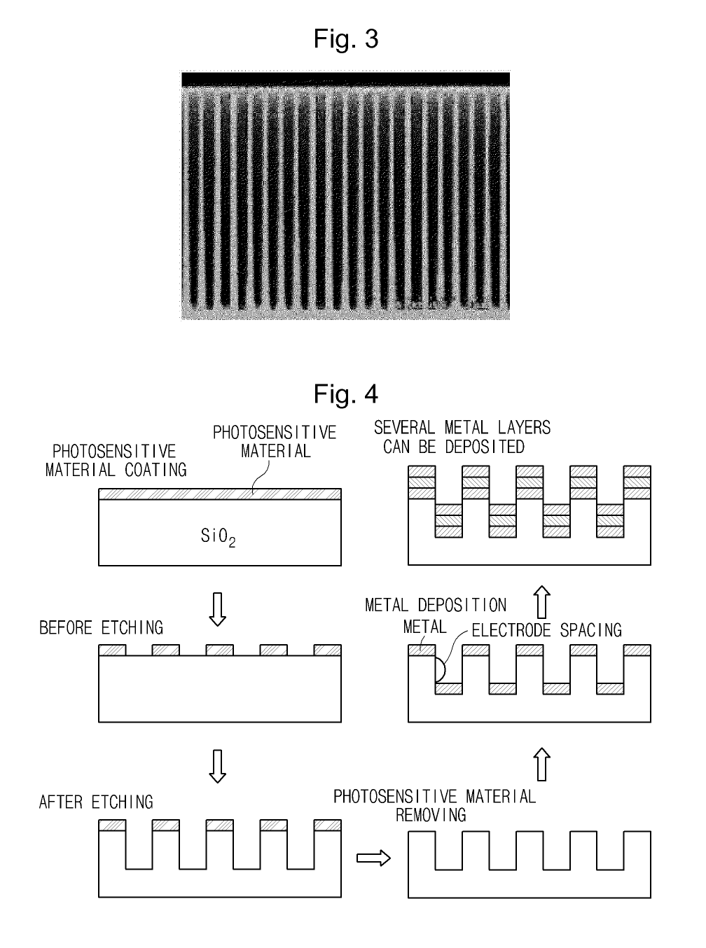

In order to a vertical electrode, the trench structure may be used. A typical trench structure is illustrated in FIG. 3. FIG. 3 is a view illustrating an example of the trench structure.

The trench structure may be formed by performing a selective anisotropic etching process on the substrate. The etching is a process of selectively exposing a material and, after that, removing an exposed portion of the material by using a highly reactive gas or liquid. As the type of the etching, there are physical etching, chemical etching, and combinational etching thereof.

After the formation of the trench region (S110), electrode layers are formed in predetermined regions of inner or outer portions of the trench. Herein, the predetermined regions also denote regions which are defined in advance by a semiconductor designer or the like in order to form the electrode layers.

At this time, the electrode layers may be formed as a plurality of electrode layers separated from each other by insulating layers. In this case, the vertical electrode structure can be implemented in more various forms. FIG. 4 is a flowchart illustrating a process of forming the vertical electrode structure using the trench having a plurality of the electrode layers.

In FIG. 4, it can be seen that the electrode layers are formed by using a deposition process. In this manner, in the case where the electrode layers are formed by using a deposition process, a thickness of each of the deposited electrodes is adjusted by controlling an electrode deposition time, so that it is possible to easily adjust an electrode spacing.

The deposition process may be performed in the state where the substrate is tilted in a predetermined direction. In the case where the substrate is tilted in a trench sidewall direction, the adjustment of the electrode spacing can be more easily performed. In the case where the substrate is tilted in the direction parallel to the trench sidewall direction, although a highly flexible metal is deposited, it is possible to prevent undesired short-circuit between the electrodes.

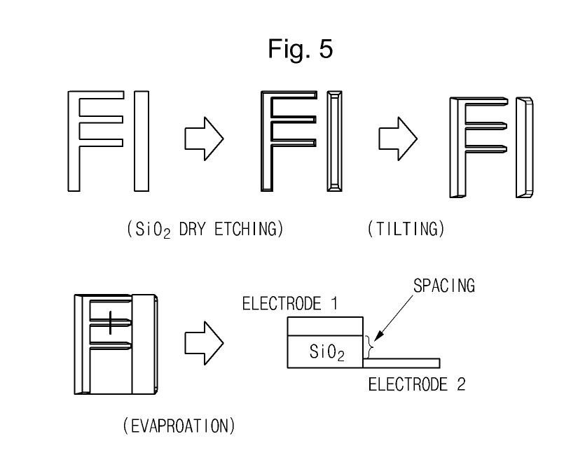

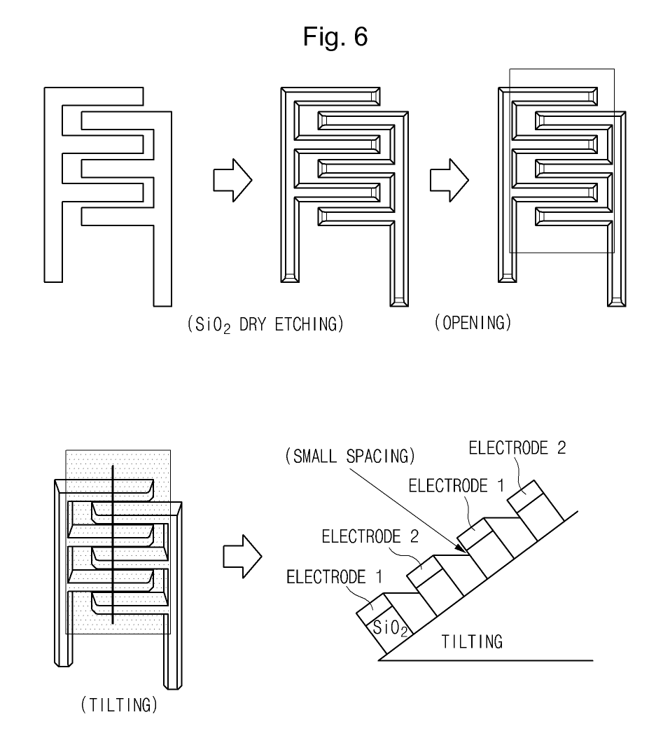

FIG. 5 is a flowchart illustrating a process of performing electrode extension by using a left-right slope, and FIG. 6 is a flowchart illustrating a process of performing electrode extension by using an up-down slope. FIGS. 5 and 6 illustrate examples where the substrate is tilted in the left-right or up-down direction, and after that, the electrode deposition is performed, so that the adjustment of the electrode spacing can be more effectively performed.

In the embodiment, in order to form the electrode layers, after the formation of the trench (S110), the substrate is tilted (S120), and after that, the electrode layers are deposited (S130).

In this manner, the electrode deposition in the vertical direction is established by using the trench, so that it is possible to form a deposited electrode having a size of several hundred nm or less by a short processing time and a low processing cost.

In the embodiment, after the electrode layer is formed, a predetermined liquid material is coated on the substrate and cured (S140), and the cured material, to which the electrode layer is transferred from the substrate, is detached from the substrate (S150). In this case, the predetermined material may be a material which is determined in advance by a semiconductor designer or manufacturer, or the like. In general, the predetermined material may be a polydimethylsiloxane (PDMS). According to the configuration, it is possible to easily form a vertical electrode structure in a flexible substrate such as PDMS.

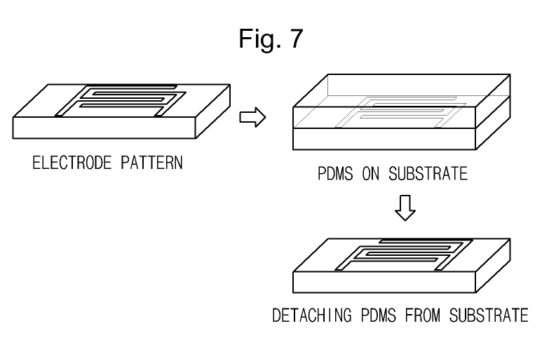

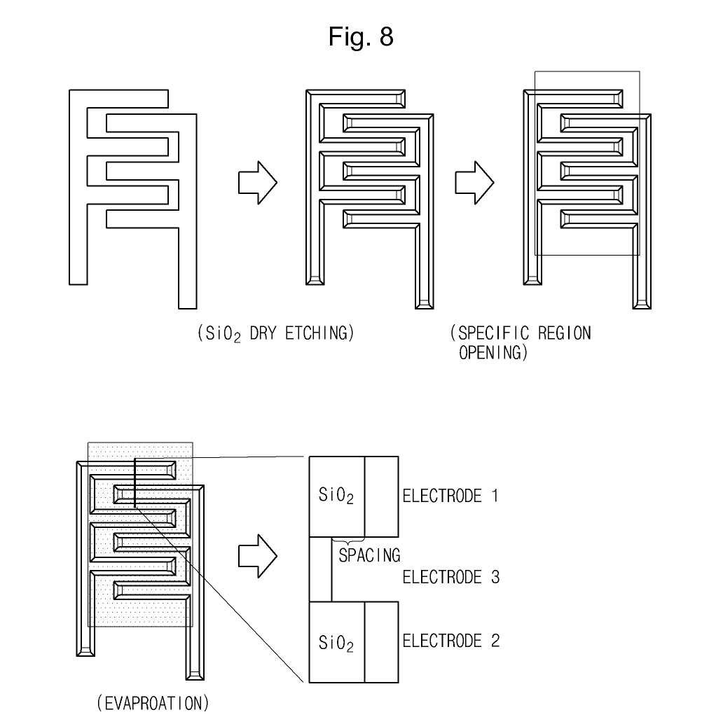

FIG. 7 is a flowchart illustrating a process of transferring an electrode pattern to a flexible substrate. The adhesiveness between gold and a general silicon-based substrate is not good. Therefore, when the flexible material such as PDMS is coated on the electrode and cured, as illustrated in FIG. 8, the electrode pattern is transferred to the PDMS.

Hereinafter, n specific example of the aforementioned embodiment will be described in detail.

In the present invention, the trench structure formed by using selective etching is adapted to manufacture electrodes. Therefore according to the present invention, electrode spacing is adjusted according to the deposition thickness by using the etching process and the shading deposition process, so that it is possible to perform mass production of the electrodes having narrow spacing.

As described in the background technology, in order to decrease the electrode spacing down to several hundred nm or less by using a horizontal electrode structure, a precision technology such as electron beam lithography is needed, and much time is taken. Therefore, there are problems in that the conventional technology is not appropriate to the large-area production process and the product cost is high. In addition, a process of forming the interdigitated electrode having several electrodes while maintaining fine electrodes is a process which is highly difficult in terms of techniques.

In order to solve these problems, in the present invention, the vertical electrode structure is formed by using selective anisotropic etching. According to the configuration, it is possible to form general silicon-based electrodes and also to form electrode on a substrate which is formed by using a flexible material such as PDMS.

In this manner, due to the vertical electrode structure using the trench structure according to the present invention, it is possible to form electrode spacing of several hundred nm or less which is appropriate to a large-area production process. After a deep trench structure is formed, metal is deposited inside and outside of the trench structure, and the electrodes are separated in the vertical direction, so that the electrode spacing can be adjusted by the deposition thickness of the electrode. In general, the deposition rate can be controlled to be at the level of 10⁻¹⁰ m/s.

Since the deposition process or the etching process can be performed in unit of a wafer, the processing rate thereof is rapid, and these processes are appropriate to a large-area production process. In addition, metal is deposited while the etched wafer is tilted, it is possible to form an electrode structure by using a highly soft metal, and it is possible to form a new electrode in addition to the previously-formed electrodes.

In addition, by a process of coating a flexible substrate such as PDMS on the formed electrode, which is described above, and detaching the substrate, it is possible to easily form fine electrodes on the flexible substrate.

In addition, the vertical electrode structure is formed by using the selective etching, so that it is possible to form various forms of electrodes having a narrow electrode spacing. Theretofore, the electrode area capable of receiving electrical signals is increased and the electrode spacing is decreased, so that it is possible to increase a measured current or a capacitance value. Therefore, it is possible to enlarge the electrical signals. The electrodes are separated from each other in the vertical direction but the electrodes are not separated in the horizontal direction. Therefore, the size of the element is reduced, so that the configuration can be expected to be contributed to the integration.

In addition, particularly, in the case where electrodes are formed by using an interdigitated electrode pattern which is formed in advance, it is possible to form 3-terminal interconnection. In the case where electrodes are formed by using the up-down slope, it is possible to easily control the electrode spacing.

In addition, since the etching process and the deposition process used in the present invention are widely used as semiconductor manufacturing processes, there is an advantage in that the present invention can be adapted to a semiconductor large-area process. In addition, the present invention can be adapted to electrode formation in a flexible substrate through transferring as well as a general silicon-based substrate.

In the present invention, first, a photosensitive material is patterned on the substrate through a photolithography process, and after that, the substrate is etched by using the photosensitive material as a mask through an appropriate etching process. At this time, the etching depth is determined according to a thickness of the to-be-deposited metal layer.

Next, after the remaining photosensitive material is removed, a metal layer is deposited, so that the metal layer is disposed on the upper portion of the substrate and the etched portion of the substrate (refer to FIG. 4). At this time, if the metal layer having a thickness smaller than the etching depth is deposited, the separated metal layer can be obtained.

In addition, if one side of the substrate is deposited in the state where the substrate is tilted, the electrode can be intentionally extended, so that new electrodes which are not in contact with original electrodes and having a short electrode spacing can be formed between the interdigitated electrodes, in which the only one-side electrode is prepared (refer to FIG. 5). The substrate is tilted in the direction vertical to the foot direction of the interdigitated electrode, so that the electrode spacing can be changed (refer to FIG. 6).

In addition, in the case where the interdigitated electrodes are formed at the two sides, a new electrode is formed between the two electrodes, so that 3-terminal interconnection is formed (refer to FIG. 8). FIG. 8 is a flowchart illustrating an electrode formation process using the interdigitated electrode pattern. In FIG. 8, it can be seen that the 3-terminal interconnection is formed by using the interdigitated electrode.

In addition, if a flexible material such as PDMS is coated on the formed electrode pattern and cured, the electrode pattern is transferred to the PDMS due to a relatively weak adhesive force between gold and the silicon substrate (refer to FIG. 7).

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A method of forming a vertical electrode structure using a trench, comprising steps of:
forming the trench on a predetermined region of a semiconductor substrate; and
forming electrode layers in predetermined regions of inner and outer portions of the trench.

2. The method according to claim 1, wherein the electrode layers are formed by using a deposition process.

3. The method according to claim 2, wherein the deposition process is performed in the state where the substrate is tilted in a predetermined direction.

4. The method according to claim 1, wherein the electrode layers are formed as a plurality of electrode layers which are separated from each other by insulating layers.

5. The method according to claim 1, further comprising steps of:
coating a predetermined liquid material on the substrate and curing the liquid material; and
detaching the cured material, to which the electrode layer is transferred from the substrate, from the substrate.

6. The method according to claim 5, wherein the material is polydimethylsiloxane (PDMS).

7. A vertical electrode structure using a trench, comprising:
a trench which is formed on a predetermined region of a semiconductor substrate; and
electrode layers which are formed in predetermined regions of inner and outer portions of the trench.

8. The vertical electrode structure according to claim 7, wherein the electrode layers are formed so as to be tilted by a predetermined angle with respect to a sidewall of the trench.

9. The vertical electrode structure according to claim 7, wherein the electrode layers are formed as a plurality of electrode layers which are separated from each other by insulating layers.
